(19) United States
(12) Patent Application Publication
(10) Pub. No.: US 2026/0164659 A1
(43) Pub. Date: Jun. 11, 2026

(54) SEMICONDUCTOR DEVICE AND FABRICATION METHODS THEREOF

(71) Applicant: Yangtze Memory Technologies Co., Ltd., Wuhan (CN)

(72) Inventors: Hao ZHANG, Wuhan (CN); Gang ZHANG, Wuhan (CN); Yan ZHANG, Wuhan (CN); Meng XIAO, Wuhan (CN); Xinglin PENG, Wuhan (CN); Renyu WEI, Wuhan (CN)

(21) Appl. No.: 19/030,125

(22) Filed: Jan. 17, 2025

(30) Foreign Application Priority Data
Dec. 5, 2024 (CN) 202411786954.X

(51) Int. Cl. H10B 43/27; H01L 21/762; H10B 43/10; H10B 43/35

(52) U.S. Cl. CPC H10B 43/27; H10B 43/10; H10B 43/35; H10W 10/014; H10W 10/17

(57) ABSTRACT

The present disclosure relates to methods, devices, systems, and techniques for managing isolating structures in semiconductor devices. An example semiconductor device includes a stack of conductive layers and isolating layers alternating with each other along a first direction and channel structures that extend through the stack. The example semiconductor device also includes conductive structures that extend through the dielectric layer, where the conductive structures are connected to the corresponding channel structures, and where a length of a first end of a first conductive structure of the conductive structures is greater than a length of the channel structure along a second direction perpendicular to the first direction, and an isolation structure that extends through the dielectric layer and at least one conductive layer of the stack along the first direction.

### CROSS-REFERENCE TO RELATED APPLICATIONS

This application claims priority to Chinese Patent Application No. 202411786954.X, filed on Dec. 5, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing contact structures in semiconductor devices.

One aspect of the present disclosure features a semiconductor device. The semiconductor device includes a stack of conductive layers and isolating layers alternating with each other along a first direction; a channel structure that extends through the stack, where the channel structure includes a first end and a second end opposite to each other along the first direction; a dielectric layer including a first dielectric material and located on a side of the stack along the first direction; a first conductive structure that extends through the dielectric layer, where the first conductive structure is connected to the corresponding channel structure, where the first conductive structure includes a first end and a second end opposite to each other along the first direction, and where a length of the first end of a first conductive structure is greater than a length of the first end of the channel structure along a second direction perpendicular to the first direction, the first end of the first conductive structure being farther away from the stack than the second end, and the first end of the channel structure being closer to the dielectric layer than the second end; and an isolation structure that extends through the dielectric layer and at least one conductive layer of the stack along the first direction.

In some implementations, the isolation structure is between two adjacent channel structures along the second direction, and where the isolation structure is spaced from the channel structures along the second direction.

In some implementations, the semiconductor device further includes an insulating layer located between the stack and the dielectric layer, and where the isolation structure extends through the insulating layer along the first direction.

In some implementations, along the second direction, the length of the first end of the first conductive structure is greater than a length of the second end of the first conductive structure, and where the second end of the first conductive structure is in contact with the first end of the channel structure along the first direction.

In some implementations, the channel structure further includes a channel plug in contact with the second end of the first conductive structure along the first direction, and where the length of the first end of the channel structure is greater than the length of the second end of the first conductive structure along the second direction.

In some implementations, the semiconductor device includes a second conductive structure having a first end and a second end opposite to each other along the first direction, where the second conductive structure is connected to the corresponding channel structure, and where the length of the first end of the first conductive structure is greater than a length of a first end of the second conductive structure along the second direction, the first end of the second conductive structure being farther away from the stack than the second end of the second conductive structure.

In some implementations, the isolation structure includes an outer layer in the dielectric layer, where the outer layer includes a second dielectric material, and where the first dielectric material of the dielectric layer is different from the second dielectric material of the outer layer of the isolation structure.

In some implementations, the semiconductor device includes a third conductive structure that is partially surrounded by the isolation structure, the third conductive structure is connected to the corresponding channel structure, and where the third conductive structure is in contact with the outer layer of the isolation structure in the dielectric layer along the second direction.

In some implementations, the first conductive structure and the second conductive structure in the dielectric layer are connected to interconnect structures through coupling-out structures.

In some implementations, a length of the first end of the second conductive structure is at least two times greater than a length of the coupling-out structure along the second direction.

Another aspect of the present disclosure features a method of forming a semiconductor device. The method includes forming a stack of conductive layers and isolating layers alternating with each other along a first direction, where the stack includes channel structure that extends through the stack along the first direction, and where the channel structure includes a first end and a second end opposite to each other along the first direction; forming a dielectric layer including a first dielectric material and located on a side of the stack along the first direction; forming a first conductive structure that extends through the dielectric layer, where the first conductive structure is connected to the corresponding channel structure, where the first conductive structure includes a first end and a second end opposite to each other along the first direction, and where a length of the first end of a first conductive structure is greater than a length of the first end of the channel structure along a second direction perpendicular to the first direction, the first end of the first conductive structure being farther away from the stack than the second end, and the first end of the channel structure being closer to the dielectric layer than the second end; and forming an isolation structure that extends through the dielectric layer and at least one conductive layer of the stack along the first direction.

In some implementations, forming the isolation structure includes etching through the dielectric layer to form a first space, where the first space is in contact with a corresponding conductive structure; deepening the first space by etching through at least one conductive layer of the stack from an end of the first space along the first direction and etching a portion of the corresponding conductive structure to from a second conductive structure, the end of the first space being connected to the stack; and filling a dielectric material into the first space to form the isolation structure, where the isolation structure is between two adjacent channel structures along the second direction, and where the isolation structure is spaced from the channel structures along the second direction.

In some implementations, the method further includes before forming the dielectric layer, forming an insulating layer by depositing a dielectric material on the end of the stack, where the insulating layer is stacked between the stack and the insulating layer, and where the conductive structure extends through the insulating layer and are connected to the corresponding channel structures.

In some implementations, forming the isolation structure further includes etching through the dielectric layer to form a second space, where the second space are in contact with a corresponding conductive structure; etching through the insulating layer at an end of the second space along the first direction, the end of the second space being connected to the insulation layer; deepening the second space by etching through at least one conductive layer of the stack from the end of the second space along the first direction and etching a portion of the corresponding conductive structure to from a second conductive structure; and filling a dielectric material into the second space to form the isolation structure, where the isolation structure is between two adjacent channel structures along the second direction, and where the isolation structure is spaced from the channel structures along the second direction.

In some implementations, the second conductive structure includes a first end and a second end opposite to each other along the first direction, and where the length of the first end of the first conductive structure is greater than a length of a first end of the second conductive structure along the second direction, the first end of the second conductive structure being farther away from the stack than the second end.

In some implementations, the isolation structure further includes an outer layer in the dielectric layer, and where the forming the isolation structure includes etching through the dielectric layer to form a third space, where the third space are in contact with a corresponding conductive structure; depositing an insulating layer on an inner wall of the third space; deepening the third space by etching through the insulating layer and at least one conductive layer of the stack from an end of the third space along the first direction, the end of the third space being connected to the stack; and filling a dielectric material into the third space to form the isolation structure, where the isolation structure is between two adjacent channel structures along the second direction, the isolation structure is spaced from the channel structures along the second direction.

In some implementations, the semiconductor device further includes a third conductive structure that is partially surrounded by the isolation structure, and where the third conductive structure is in contact with the outer layer of the isolation structure in the dielectric layer along the second direction.

In some implementations, the method further includes forming coupling-out structures, where the first conductive structure and the second conductive structure in the dielectric layer are connected to interconnect structures through the coupling-out structures.

In some implementations, a length of the first end of the second conductive structure is at least two times greater than a length of the coupling-out structure along the second direction.

A further aspect of the present disclosure features a memory system. The memory system includes a memory device and a memory controller coupled to the memory device and configured to control the memory device. The memory device includes a stack of conductive layers and isolating layers alternating with each other along a first direction; a channel structure that extends through the stack, where the channel structure includes a first end and a second end opposite to each other along the first direction; a dielectric layer including a first dielectric material and located on a side of the stack along the first direction; a first conductive structure that extends through the dielectric layer, where the first conductive structure is connected to the corresponding channel structure, where the first conductive structure includes a first end and a second end opposite to each other along the first direction, and where a length of the first end of a first conductive structure is greater than a length of the first end of the channel structure along a second direction perpendicular to the first direction, the first end of the first conductive structure being farther away from the stack than the second end, and the first end of the channel structure being closer to the dielectric layer than the second end; and an isolation structure that extends through the dielectric layer and at least one conductive layer of the stack along the first direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIG. 1 illustrates a top view of an example semiconductor device.

FIG. 2A illustrates a top view of an example semiconductor device.

FIG. 2B illustrates a cross-section view of an example semiconductor device of FIG. 2A.

FIG. 2C illustrates a top view of an example semiconductor device of FIG. 2A.

FIG. 2D illustrates a top view of an example semiconductor device.

FIG. 2E illustrates a cross-section view of an example semiconductor device of FIG. 2D.

FIG. 2F illustrates a top view of an example semiconductor device of FIG. 2D.

FIGS. 3A to 3F show cross-sectional views of structures of a 3D semiconductor device of FIG. 2A at various stages of a fabrication process.

FIGS. 4A to 4G show cross-sectional views of structures of a 3D semiconductor device of FIG. 3D at various stages of a fabrication process.

FIG. 5 illustrates a flow chart of an example process of manufacturing a semiconductor device.

FIG. 6 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the demand for cheaper memory devices with higher density, a memory device (e.g., a 3D NAND flash memory) can be formed with a large number of layers and a high aspect ratio. The large number of layers and the high aspect ratio of such memory devices may bring challenges to the manufacturing process. For example, the large number of layers requires a larger area for the connection regions of each conductive layer of the memory device, which necessitates additional dummy channel arrays during the fabrication process. In other words, the large area of the connection regions and the additional dummy channel arrays may pose challenges to increasing the density of the memory device. Another method to form the connection region requires an additional isolation deck on top of the conductive structure, which increases the fabrication cost and steps, thus increasing the complexity of the fabrication process. Therefore, fabrication methods that can solve the aforementioned issues are desirable.

In one or more implementations of the present disclosure, an example semiconductor device is provided. The semiconductor device includes a stack of conductive layers and isolating layers alternating with each other along a first direction and channel structures that extend through the stack, where each channel structure of the channel structures includes a first end and a second end opposite to each other along the first direction. The semiconductor device also includes a dielectric layer including a first dielectric material and located on a side of the stack along the first direction and conductive structures that extend through the dielectric layer, where the conductive structures are connected to the corresponding channel structures. Each conductive structure of the conductive structures includes a first end and a second end opposite to each other along the first direction, where a length of the first end of a first conductive structure of the conductive structures is greater than a length of the first end of the channel structure along a second direction perpendicular to the first direction, the first end of the first conductive structure being farther away from the stack than the second end, and the first end of the channel structure being closer to the dielectric layer than the second end. The semiconductor device can further include an isolation structure that extends through the dielectric layer, at least one conductive layer of the stack along the first direction.

Implementations of the present disclosure can provide one or more of the following technical advantages and/or benefits. First, the isolation structure in the present disclosure can be formed without the requirement of the dummy channel structure. In other words, the isolation structure helps to reduce the area of the connection region, which improves the device density. Second, the isolation structure discussed in the present disclosure can be formed on the same deck as the conductive structure, which simplifies the fabrication process. In other words, the conductive structure serves as a mask for the isolation structure, reducing the need for high-resolution lithography tools during the fabrication process. Third, the conductive layers in the stack of the semiconductor device serve as an etch stop layer to control the depth of the isolation structure, offering simple process control of the semiconductor device.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

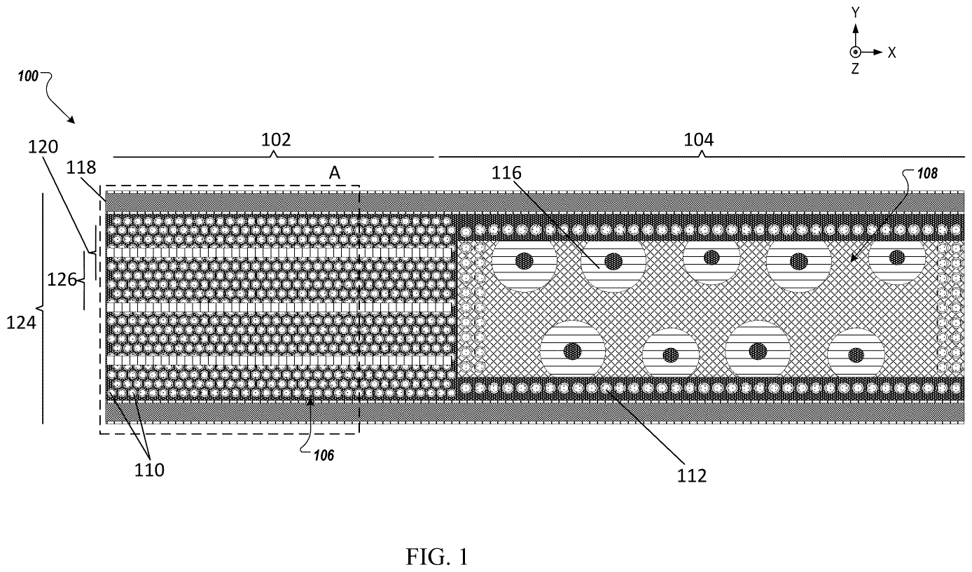

It is noted that X, Y, and Z axes (also referred to as X, Y, and Z directions) are included in FIG. 1 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1 illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1, the semiconductor device 100 includes an array region 102 and a connection region 104 adjacent to the array region 102 along a first horizontal direction (e.g., the X direction). It is understood that the example in FIG. 1 is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

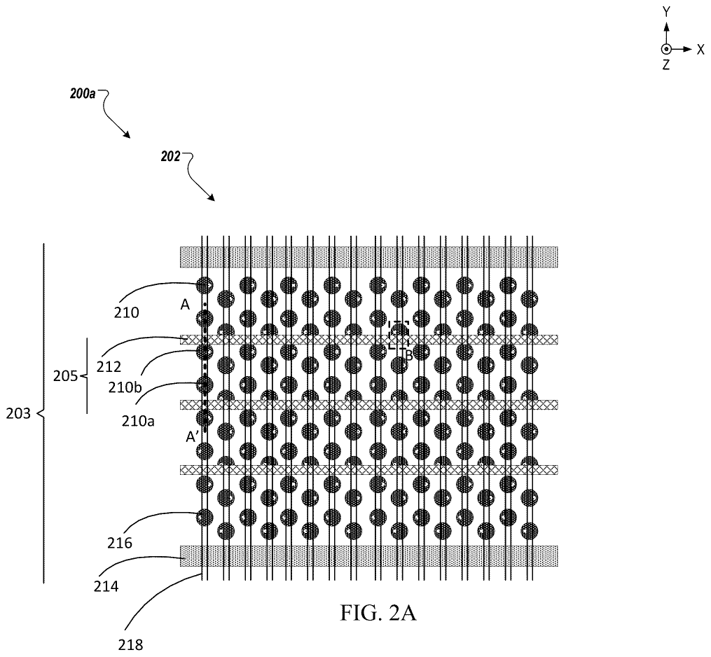

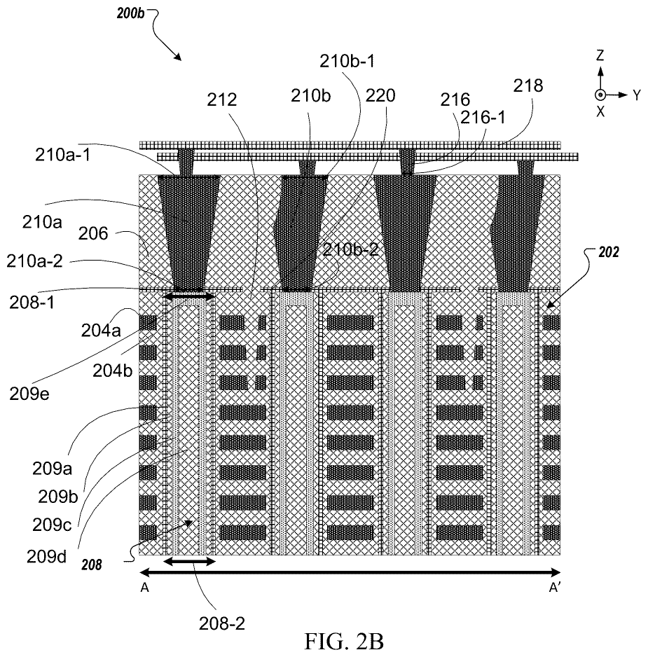

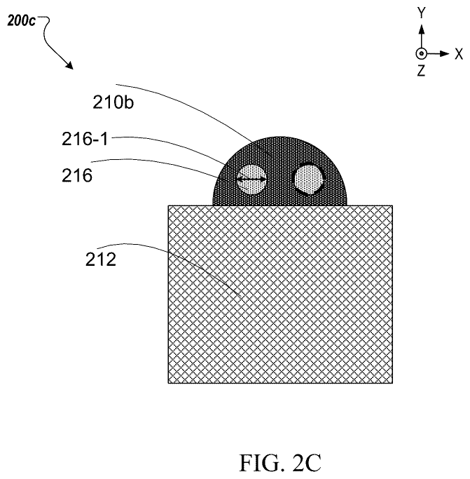

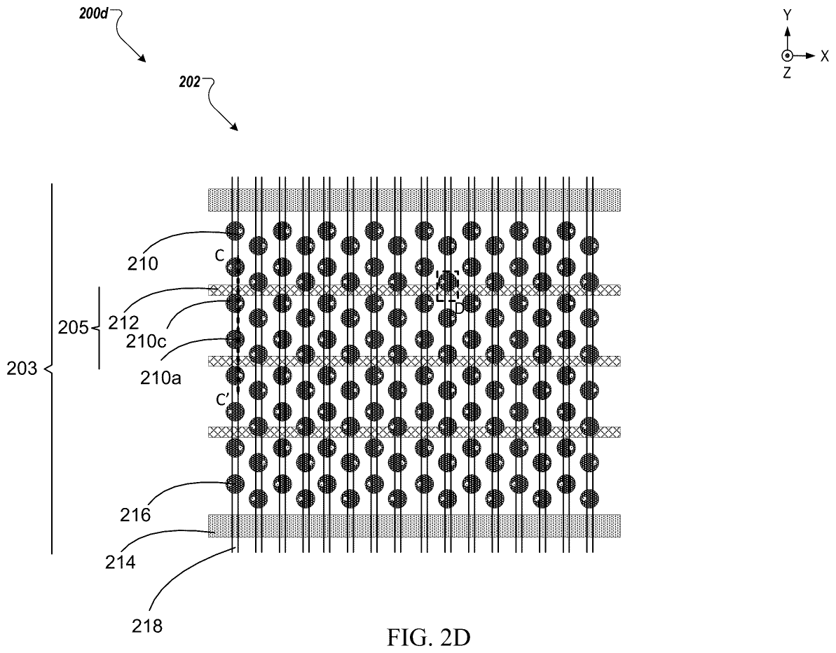

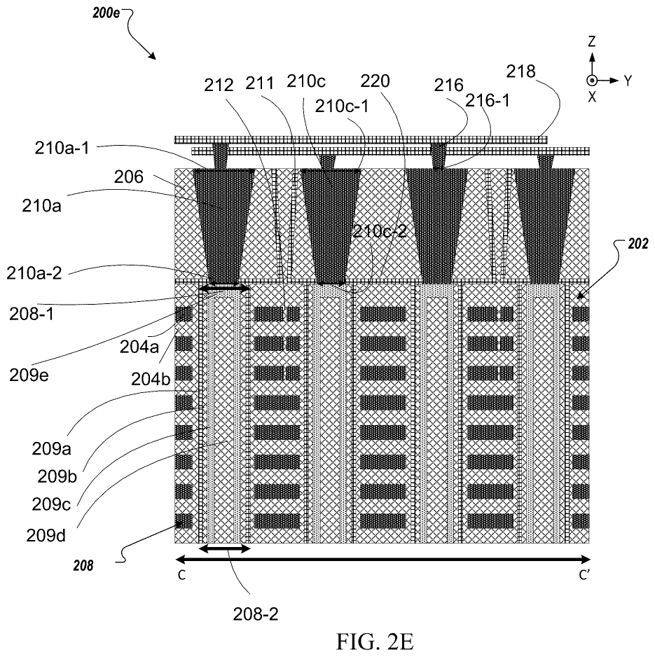

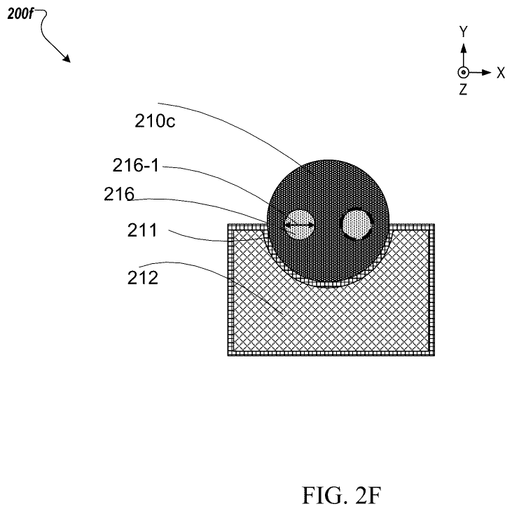

The semiconductor device 100 includes a stack 106 of alternating conductive layers and isolating layers (e.g., conductive layers 204a and isolating layers 204b as shown in FIG. 2B or FIG. 2E). In some implementations, a part of the stack 106 can be in the array region 102, and another part of the stack 106 can be in the connection region 104. In some implementations, as shown in FIG. 1, the stack 106 can further include a dielectric layer (e.g., the dielectric layer 206 of FIG. 2B or FIG. 2E) stacked on top of the alternating conductive layers and isolating layers along the Z direction. The semiconductor device 100 further includes a stack 108 of alternating dielectric layers and isolating layers. In some implementations, the stack 108 can be in the connection region 104. The stack 106 is connected to the stack 108.

The semiconductor device 100 can include an array of channel structures (not shown in FIG. 1) extending through the stack 106 in the array region 102. Each channel structure can be used to form a string of memory cells coupled in serial along a vertical direction (e.g., Z direction) perpendicular to the first horizontal direction (e.g., the X direction). In some implementations, as shown in FIG. 1, the semiconductor device 100 can also include conductive structures 110 that extend through the dielectric layer. The conductive structures 110 are connected to the corresponding channel structures of the stack 106 in the array region 102 of the semiconductor device 100. In some implementations, the semiconductor device 100 can include dummy channel structures 112 (also referred to as dummy memory strings) for process variation control during fabrication and/or for additional mechanical support. The dummy channel structures 112 can extend through the stack 106 and/or the stack 108. In some implementations, the dummy channel structures 112 are in the connection region 104. For example, some dummy channel structures 112 can be in the stack 108. In some implementations, the dummy channel structures 112 are in the array region 102 (e.g., an area adjacent to the connection region 104). In some implementations, the dummy channel structures 112 have structures identical or substantially similar to that of the channel structures.

As shown in FIG. 1, the semiconductor device 100 can include contact structures 116 in the connection region 104. A contact structure 116 can be configured to connect a corresponding one of the conductive layers of the stack 106 to a control circuit. The semiconductor device 100 can include one or more gate line structures 118. Each gate line structure 118 can extend in the X direction. The gate line structure 118 can extend into both the array region 102 and the connection region 104. In some implementations, the gate line structures 118 can divide an array region 102 into multiple memory blocks 124. In some implementations, the gate line structure 118 can function as a common source contact for the channel structures in the array region 102. In some implementations (not shown in FIG. 1), the gate line structure 118 can further include one or more segments extending along a second horizontal direction (e.g., the Y direction). In some implementations, the gate line structure 118 can include multiple segments connected in an H shape or a T shape.

The semiconductor device 100 can include isolation structure 120. The isolation structure 120 extends through the dielectric layer and at least one conductive layer of the stack 106 along the Z direction. In some implementations, as shown in FIG. 1, the isolation structure 120 extends along the X direction in the array region 102. In some implementations, the isolation structure 120 is connected to the conductive structures 110 in the array region 102 along a second horizontal direction (e.g., the Y direction) perpendicular to the X direction and the Z direction. In some implementations, the isolation structures 120 extend along the X direction in the array region 102. In some implementations, the isolation structures 120 divided a memory block 124 of an array region 102 into one or more memory block finger 126.

FIG. 2A illustrates a top view of an example semiconductor device 200a zoomed in on zone A of the FIG. 1. As shown in FIG. 2A, the semiconductor device 200a includes a stack 202 of alternating conductive layers and isolating layers (e.g., conductive layers 204a and isolating layers 204b as shown in FIG. 2B). The semiconductor device 200a can include an array of channel structures (e.g., the channel structure 208 of FIG. 2B) extending through the stack 202 along a vertical direction (e.g., the Z direction). In some implementations, the stack 202 can further include a dielectric layer (e.g., the dielectric layer 206 of FIG. 2B) stacked on top of the alternating conductive layers and isolating layers along the Z direction. In some implementations, as shown in FIG. 2A, the semiconductor device 200a can include conductive structures 210 that extend through the dielectric layer. The conductive structures 210 are connected to the corresponding channel structures 208 of the stack 202 along the Z direction. In some implementations, the conductive structures 210 are in contact with the corresponding channel structures 208 of the stack 202 along the Z direction. In some implementations, the conductive structure 210 can be similar to, or same as the conductive structures 110 of the semiconductive device 100 of FIG. 1.

As shown in FIG. 2A, the semiconductive device 200a can include isolation structure 212 extends along a horizontal direction (e.g., the X direction) perpendicular to the Z direction. The isolation structure 212 extends through a portion of the corresponding conductive structure 210 along a second horizontal direction (e.g., the Y direction) perpendicular to the Z direction and the X direction. In some implementations, the isolation structure 212 extends through the dielectric layer 206 and one conductive layer 204a of the stack 202 along the Z direction. In some implementations, the isolation structure 212 can be similar to, or same as the isolation structure 120 of the semiconductor device 100 of FIG. 1. The semiconductor device 200a can include one or more gate line structures 214. Each gate line structure 214 can extend in the X direction and divide the stack 202 into one or more blocks 203. In some implementations, the gate line structure 214 can be similar to, or same as the gate line structure 118 of the semiconductor device 100 of FIG. 1. In some implementations, the isolation structures 212 extend along the X direction in the stack 202. In some implementations, the isolation structures 212 divided a memory block 203 of the stack 202 into one or more memory block finger 205.

In some implementations, the semiconductor device 200a can further include a coupling-out structures 216 connected to the corresponding conductive structure 210 along the Z direction. The coupling-out structures 216 extend in the Y direction. In some implementations, the conductive structures 210 in the dielectric layer 206 are connected to interconnect structures 218 through the coupling-out structure 216. In some implementations, the interconnect structures 218 can be a bit line structure.

FIG. 2B illustrates a cross-sectional view of the semiconductor device 200b along cutline AA′ of the semiconductor device 200a of FIG. 2A. The semiconductor device 200b can be the semiconductor device 200a of FIG. 2A or a structure at an intermediate fabrication process of the semiconductor device 100 of FIG. 1.

As shown in FIG. 2B, the semiconductor device 200b includes a semiconductor layer (not shown in FIG. 2B), the stack 202 of alternating conductive layers 204a and isolating layers 204b. The stack 202 is provided over the substrate. The semiconductor layer can be any suitable semiconductor substrate having any suitable semiconductor material, such as monocrystalline, polycrystalline or single crystalline semiconductor. For example, the substrate can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the semiconductor layer can be removed from the semiconductor device 200b in a later process of manufacturing the semiconductor device 200b.

The conductive layers 204a and the isolating layers 204b can alternate in the vertical direction (e.g., Z direction) perpendicular to the second horizontal direction. The conductive layers 204a can be the same or different from each other in thickness, for example, ranging from 10-500 nm, e.g., about 35 nm. The isolating layers 204b can also be the same or different from each other in thickness, for example, ranging from 10-500 nm, e.g., about 25 nm. It should be noted that the number of the conductive layers 204a and the isolating layers 204b shown in FIG. 2B is for illustration only and that any suitable number of the conductive layers 204a and the isolating layers 204b can be included in the stack 202. The conductive layers 204a can include any suitable conducting material, such as tungsten (W), cobalt (Co), copper (Cu), aluminum (Al), polycrystalline silicon (polysilicon), doped silicon, silicides, or any combination thereof. In some implementations, the isolating layers 204b can include a dielectric material, such as silicon oxide, silicon nitride, silicon oxynitride, or any combination thereof. In some implementations, the isolating layers 204b can also include high-K dielectric materials, such as hafnium oxide, zirconium oxide, aluminum oxide, tantalum oxide, lanthanum oxide, or any combination thereof.

The semiconductor device 200b can include channel structures 208 extending through the stack 202. In some implementations, each channel structure 208 of the channel structures 208 can include a first end 208-1 and a second end 208-2 along the Z direction. Each channel structure 208 can extend through the stack 202 along the Z direction. In some examples, the channel structure 208 can be in the shape of a cylinder or a pillar, and can include a dielectric outer layer 209a, a block layer surrounded by the outer layer, a charge trapping layer (or a storage layer) surrounded by the block layer, a tunneling layer surrounded by the charge trapping layer, a channel layer 209c surrounded by the tunneling layer, and a core filler layer 209d surrounded by the channel layer 209c, and a channel plug 209e formed above the core filler layer 209d and being in contact with the channel layer 209c. In some implementations, the channel layer 209c can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the tunneling layer, the charge trapping layer, and the blocking layer, collectively referred to as a memory film 209b, can include ONO dielectrics (silicon Oxide-silicon Nitride-silicon Oxide).

As shown in FIG. 2B, the semiconductor device 200b can include a dielectric layer 206 stacked on top of the stack 202 along the Z direction. In some implementations, the semiconductor device 200b can also include conductive structures 210 extend through the dielectric layer 206 along the Z direction. The conductive structures 210 are connected to the corresponding channel structures 208 along the Z direction. In some implementations, the conductive structures 210 can include a first conductive structure 210a, where the first conductive structure 210a can include a first end 210a-1 and a second end 210a-2. In some implementations, a length of the first end 210a-1 of the first conductive structure 210a of the conductive structures 210 is greater than a length of the first end 208-1 of the channel structure 208 along the Y direction. The first end 210a-1 of the first conductive structure 210a is farther away from the stack 202 than the second end 210a-2 of the first conductive structure 210a. In some implementations, the first end 208-1 of the channel structure 208 is closer to the dielectric layer 206 than the second end 208-2. In some implementations, the first end 208-1 of the channel structure is the contact region between the channel structure 208 and the corresponding conductive structure 210 along the Y direction.

The semiconductor device 200b can include an isolation structure 212. The isolating structure 212 extends through the dielectric layer 206 and at least one conductive layer of the stack 202 along the Z direction. In some implementations, the dielectric layer 206 can include a dielectric material, such as silicon oxide, silicon nitride, silicon oxynitride, or any combination thereof. In some implementations, the isolation structure 212 is between two adjacent channel structures 208 along the Y direction, and the isolation structure 212 is spaced from the channel structures 208 along the Y direction. In some implementations, the isolation structure 212 can include a dielectric material similar to, or same as the dielectric material of the dielectric layer 206. In some implementations, the isolation structure 212 can include a dielectric material, such as silicon oxide, silicon nitride, silicon oxynitride, or any combination thereof. In some implementations, a dielectric material of the isolation structure 212 can be similar to, or same as a dielectric material of the isolating layer 204b. In some implementations, the conductive structures 210 can be used as a protective structure to protect the channel structures 208 during a later process of manufacturing the semiconductor device 200b. For example, the greater length of the first end 210a-1 of the conductive structures 210 compared to the end 208-1 of the channel structure 208 protects the channel structure 208 during the formation of the isolation structure 212.

In some implementations, the semiconductor device 200b can include an insulating layer 220 stacked between the stack 202 and the dielectric layer 206. The isolation structure 212 extends through the insulating layer 220 along the Z direction. In some implementations, along the Y direction, the length of the first end 210a-1 of the first conductive structure 210a is greater than a length of a second end 210a-2 of the first conductive structure 210a. The second end 210a-2 of the first conductive structure 210a is on opposite side of the first end 210a-1 of the first conductive structure 210a along the Z direction, and the second end 210a-2 of the first conductive structure 210a is in contact with the first end 208-1 of the corresponding channel structure 208 along the Z direction. In some implementations, the insulating layer 220 can include a dielectric material, such as silicon oxide, silicon nitride, silicon oxynitride, or any combination thereof. In some implementations, the insulating layer 220 can also include high-K dielectric materials, such as hafnium oxide, zirconium oxide, aluminum oxide, tantalum oxide, lanthanum oxide, or any combination thereof. In some implementations, a dielectric material in the isolation structure 212 is different from a dielectric material of the insulating layer 220. For example, the isolation structure 212 can include silicon oxide and the insulating layer 220 can include silicon nitride.

In some implementations, the channel plug 209e of the channel structure 208 is connected to the corresponding conductive structure 210 along the Z direction, where the length of the end 208-1 of the channel structure 208 is greater than the length of the second end 210a-2 of the first conductive structure 210a. In some implementations, the length of the first end 208-1 one the channel structure is a length of a contact region between the conductive structure 210 and the channel structure 208 along the Y direction. In some implementations, a length of channel plug 209e is greater than the length of the first end 208-1 of the channel structure 208 along the Y direction. In some implementations, the conductive structures 210 in the dielectric layer 206 are coupled to the interconnect structures 218 through the coupling-out structures 216.

In some implementations, as shown in FIG. 2B, the conductive structures 210 can include a second conductive structure 210b in contact with the corresponding isolation structure 212. In some implementations, the second conductive structure 210b can include a first end 210b-1 and a second end 210b-2, where the first end 210b-1 of the second conductive structure 210b is farther away from the stack 202 than the second end 210b-2 of the second conductive structure 210b along the Z direction. The length of the first end 210a-1 of the first conductive structure 210a is greater than a length of the first end 210b-1 of the second conductive structure 210b. In some implementations, the second conductive structure 210b can be used as a protective structure to protect the channel structure 208 during the formation of the isolation structure 212, where a portion of the conductive material on the first end 210b-1 of the second conductive structure 210b is etched during the fabrication of the isolation structure 212. In some implementations, the isolation structure 212 is in contact with the second conductive structure 210b along the Y direction, where the isolation structure 212 is spaced from the first conductive structure 210a along the Y direction. In some implementations, the coupling-out structures are in contact with the first ends 210a-1 and 210b-1 of corresponding conductive structures 210a and 210b. A length of the first ends 210a-1 and 210b-1 of corresponding conductive structures 210a and 210b are at least two times greater than a length of an end 216-1 of the coupling-out structures 216 along the Y direction, the end 216-1 of the coupling-out structure 216 is connected to the corresponding conductive structure 210 along the first direction. For example, as shown in FIG. 2A, two adjacent of the conductive structures 210a and 210b are connected to two interconnect structures 218 through corresponding coupling-out structures 216, where the two interconnect structures 218 are spaced from each other along the X direction. The corresponding coupling-out structures 216 are in contact with the corresponding conductive structures 210a and 210b and are spaced from each other along the X direction, which requires a length of each conductive structure 210a or 210b to be at least two times greater than the length of the coupling-out structure 216 so that the two adjacent coupling-out structures 216 can be separated from each other along the X direction. In some implementations, the isolation structure 212 is in contact with at least one second conductive structure 210b, where the isolation structure 212 is spaced from the first conductive structure along the Y direction.

FIG. 2C illustrates a top view of an example semiconductor device 200c zoomed in zone B of the semiconductor device 200a of FIG. 2A. The semiconductor device 200c can be the semiconductor device 200a of FIG. 2A or a structure at an intermediate fabrication process of the semiconductor device 100 of FIG. 1.

As shown in FIG. 2C, the isolation structure 212 is connected to the second conductive structure 210b along the Y direction, and the second conductive structure 210b are partially surrounded the isolation structure 212. The coupling-out structures 216 are connected to the second conductive structure 210b along the Z direction. In some implementations, a length of the first end 210b-1 of the second conductive structure 210b is at least two times greater than the length of the end 216-1 of the coupling-out structure 216 along the X direction. In some implementations, the second conductive structure 210b can be used as a protective structure to protect the channel structure 208 during the formation of the isolation structure 212. As shown in FIG. 2C, a portion of the conductive material on the first end 210b-1 of the second conductive structure 210b is etched during the fabrication of the isolation structure 212, where the second conductive structure 210b is connected to the isolation structure 212 along the Y direction.

FIG. 2D illustrates a top view of an example semiconductor device 200d zoomed in on zone A of the FIG. 1. In some implementations, the semiconductor device 200d can be similar to the semiconductor device 200a of FIG. 2A, except the isolation structure 212 includes an outer layer 211 in the dielectric layer 206, as shown in FIG. 2E, compared to the isolation structure 212 of semiconductor device 200a of FIG. 2A. As shown in FIG. 2D, the isolation structure 212 extends along the X direction in the semiconductor device 200d and connected to corresponding conductive structures 210 along the Y direction. The corresponding conductive structures 210 extend into a portion of the isolation structure 212 of the semiconductor device 200d along the Y direction. In some implementations, the isolation structures 212 extend along the X direction in the stack 202. In some implementations, the isolation structures 212 divided a memory block 203 of the stack 202 into one or more memory block finger 205.

FIG. 2E illustrates a cross-sectional view of the semiconductor device 200e along cutline CC′ of the semiconductor device 200d of FIG. 2D. The semiconductor device 200e can be the semiconductor device 200d of FIG. 2D or a structure at an intermediate fabrication process of the semiconductor device 100 of FIG. 1.

As shown in FIG. 2E, the isolation structure 212 includes the outer layer 211 in the dielectric layer 206. In some implementations, the outer layer 211 includes a dielectric material that is different from the dielectric material of the dielectric layer 206. For example, the outer layer 211 can include SiN and the dielectric layer 206 can include Silicon oxide. In some implementations, as shown in FIG. 2E, the conductive structures 210 includes a third conductive structure 210c that is partially surrounded by the corresponding isolation structure 212 along the Y direction. The third conductive structure 210c is connected to the outer layer 211 of the isolation structure 212 in the dielectric layer 206 along the Y direction. In some implementations, the outer layer 211 can be used as a protective layer to protect the channel structure 208 and the third conductive structure 210c during the formation of the isolation structure 212.

FIG. 2F illustrates a top view of an example semiconductor device 200f zoomed in zone D of the semiconductor device 200d of FIG. 2D. The semiconductor device 200f can be the semiconductor device 200d of FIG. 2D or a structure at an intermediate fabrication process of the semiconductor device 100 of FIG. 1.

As shown in FIG. 2F, the third conductive structure 210c is partially surrounded by the isolation structure 212 along the horizontal directions (e.g., the X and Y directions). In some implementations, the third conductive structure 210c is in contact with the outer layer 211 of the isolation structure 212 of the semiconductor device 200d along the Y direction. In some implementations, the third conductive structure 210c can include a first end 210c-1 and a second end 210c-2, where the first end 210c-1 of the conductive structure 210c is farther away from the stack 202 than the second end 210c-2 of the conductive structure 210c along the Z direction. In some implementations, the outer layer 211 can be used as a protective layer to protect the channel structure 208 and the third conductive structure 210c during the formation of the isolation structure 212. The coupling-out structures 216 are connected to the third conductive structure 210c along the Z direction. In some implementations, a length of the first end 210c-1 of the third conductive structure 210c is at least two times greater than the length of the end 216-1 of the coupling-out structure 216 along the X direction, the end 216-1 of the coupling-out structure 216 is connected to the corresponding conductive structure 210 along the first direction. For example, as shown in FIG. 2C, two adjacent of the conductive structures 210a and 210c are connected to two interconnect structures 218 through corresponding coupling-out structures 216, where the two interconnect structures 218 are spaced from each other along the X direction. The corresponding coupling-out structures 216 are in contact with the corresponding conductive structures 210a and 210c and are spaced from each other along the X direction, which requires a length of each conductive structure 210a or 210c to be at least two times greater than the length of the coupling-out structure 216 so that the two adjacent coupling-out structures 216 can be separated from each other along the X direction.

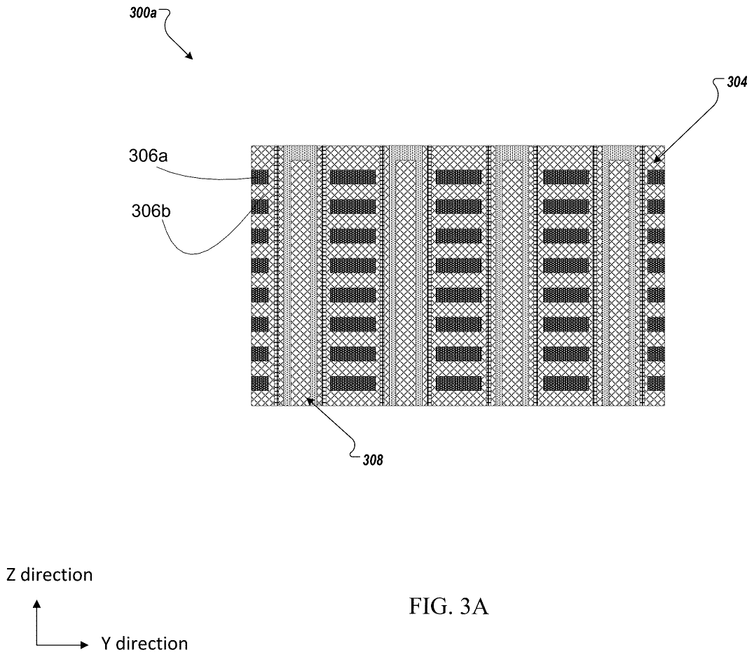

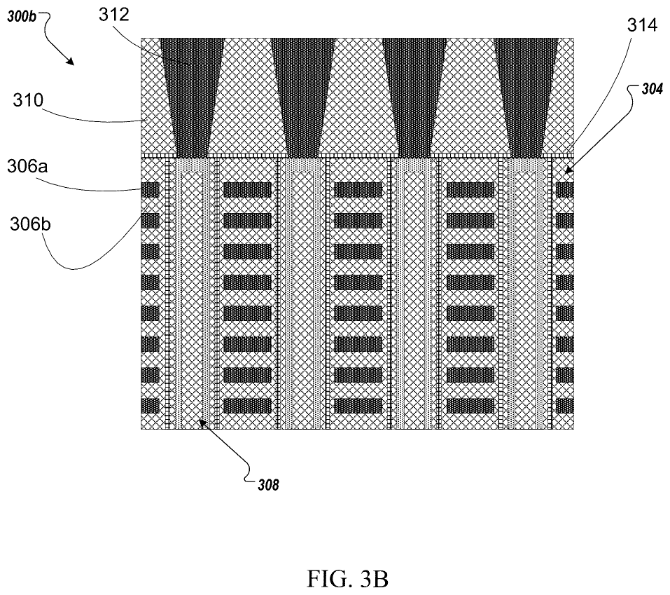

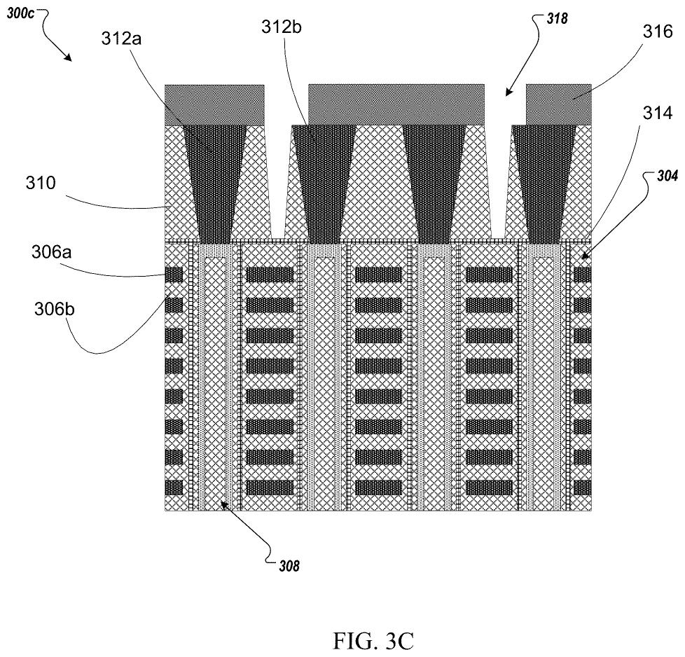

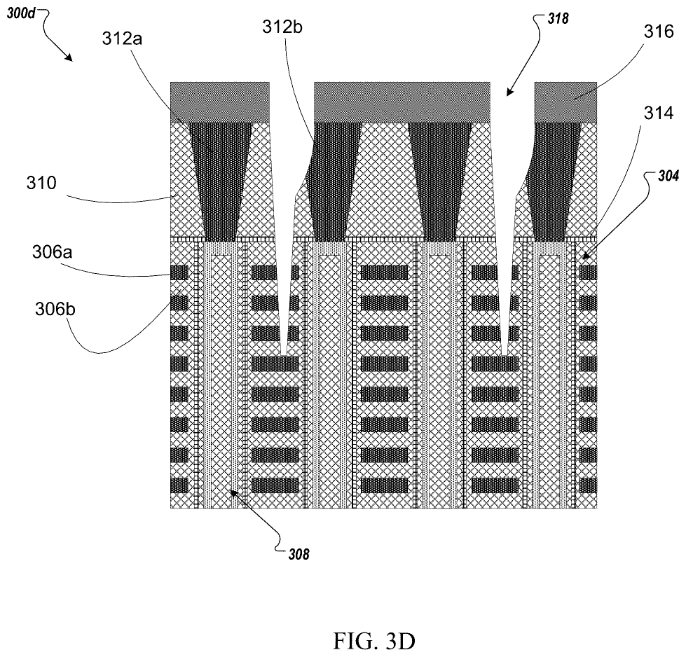

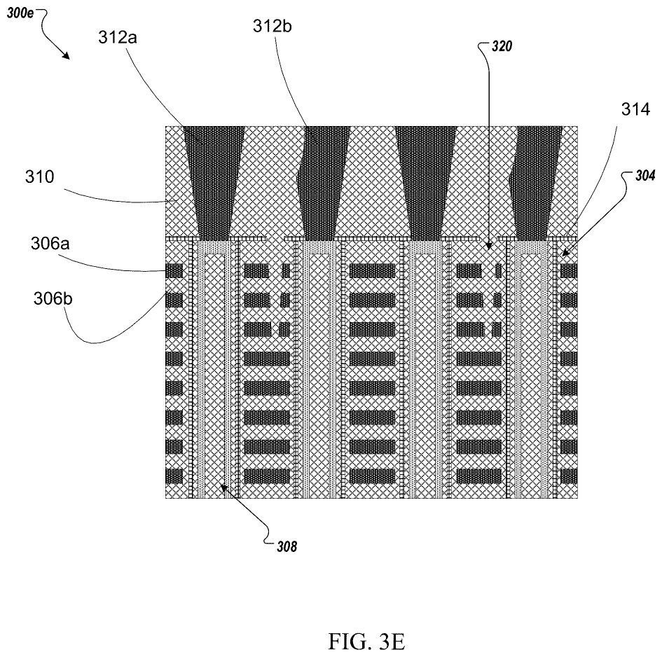

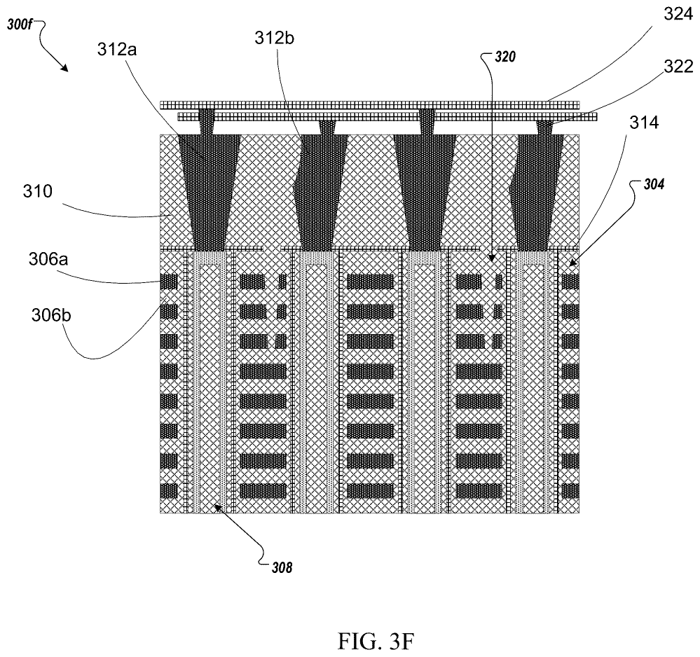

FIGS. 3A-3F illustrate an example process of fabricating a semiconductor device, such as the semiconductor device 200a as illustrated in FIG. 2A. FIGS. 3A-3F show cross-sectional views of example semiconductor structures at various stages of the fabrication process.

As shown in FIG. 3A, a semiconductor structure 300a is formed. The semiconductor structure 300a includes a stack 304 of conductive layers 306a and isolating layers 306b that alternate with each other along a vertical direction (e.g., Z direction). The semiconductor structure 300a also includes a channel structure 308 that extends through the stack 304 along the Z direction.

FIG. 3B illustrates a semiconductor structure 300b, which can be formed by depositing a dielectric material on top of the stack 304 to form a dielectric layer 310. The semiconductor structure 300b can include conductive structures 312. The conductive structures 312 are formed by etching through a portion of the dielectric layer 310 along a vertical direction (e.g., the Z direction) and filling the portion of the etched dielectric layer 310 with a conductive material. The conductive structures 312 are connected to the corresponding channel structures 308 of the stack 304 along the Z direction. In some implementations, the conductive structures 312 are in contact with the corresponding channel structures 308 of the stack 304 along the Z direction. In some implementations, the semiconductor structure 300b can also include an insulating layer 314 stacked between the dielectric layer 310 and the stack 304, which can be formed by depositing an insulating material on the stack 304 along the Z direction. In some implementations, the insulating layer 314 can be used as an etch stop layer during the fabrication process. For example, forming the conductive structure 312 includes etching a portion of the dielectric layer along the Z direction, where the etching process is stopped by the insulating layer 314, deepening the etched portion by etching through the insulation layer 314, and filling the portion of etching dielectric layer 310 with a conductive material.

FIG. 3C illustrates a semiconductor structure 300c, which can be formed by depositing a sacrificial material on top of the semiconductor structure 300b to form a sacrificial layer 316. The semiconductor structure 300c also includes one or more spaces 318. The one or more spaces 318 are formed by etching through a portion of the sacrificial layer 316 and the dielectric layer 310 along the Z direction. In some implementations, the conductive structures 312 include first conductive structures 312a and second conductive structures 312b. The one or more spaces 318 are connected to corresponding second conductive structures 312b of the semiconductor structure 300c.

FIG. 3D illustrates a semiconductor structure 300d, which can be formed by etching through at least one conductive layer 306a of the stack 304 and a portion of the second conductive structures 312b in the dielectric layer from an end of the one or more spaces 318 along the Z direction. The conductive structure 312b is used as a protective structure during the etching of the stack 304, where a portion of the conductive material of the conductive structure 312b is etched during the fabrication process to protect the channel structure 308. In some implementations, the semiconductor structure 300d include the insulating layer 314, and the semiconductor structure 300d is formed by etching through the insulating layer 314, at least one conductive layer 306a of the stack 304, and a portion of the second conductive structures 312b in the dielectric layer from the end of the one or more spaces 318 along the Z direction. The end of one or more spaces 318 is closer to the stack 304 than a surface of the dielectric layer 310.

FIG. 3E illustrates a semiconductor structure 300e, which can be formed by removing the sacrificial layer 316 and depositing a dielectric material into the one or more spaces 318 to form isolation structures 320. In some implementations, the dielectric material of the isolation structures 320 is similar to, or same as the dielectric material of the dielectric layer 310 and the dielectric material of the isolating layer 306b of the stack 304.

FIG. 3F illustrates a semiconductor structure 300f, which can be formed by depositing a conductive material on top of the conductive structures 312 to form coupling-out structures 322, where the conductive structures 312 in the dielectric layer 310 are connected to interconnect structures 324 through the coupling-out structures 322.

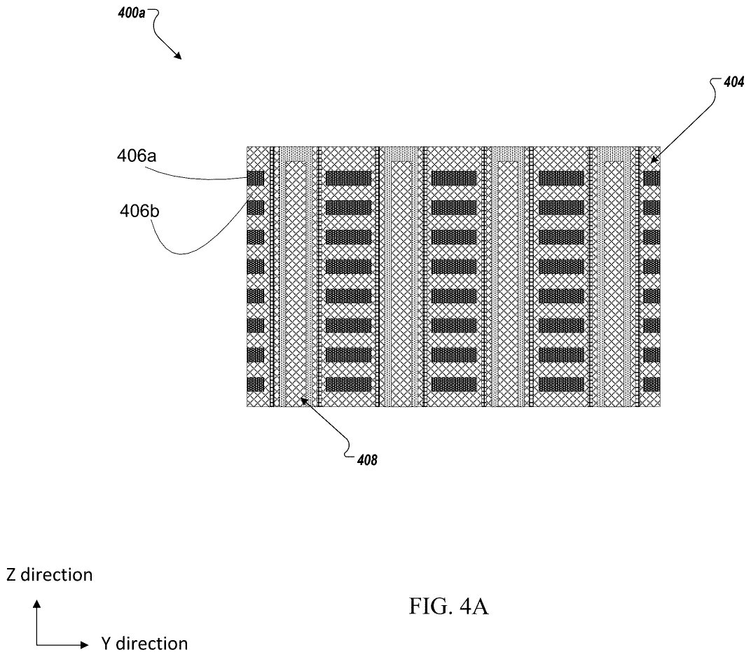

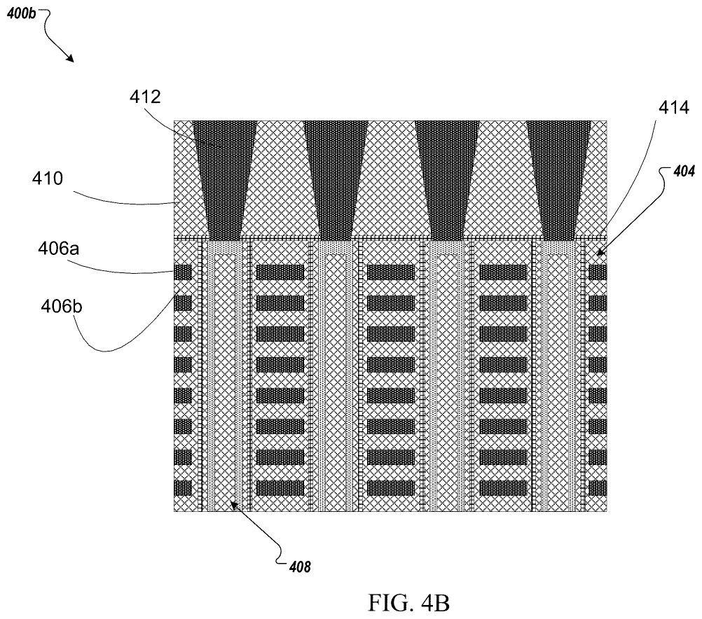

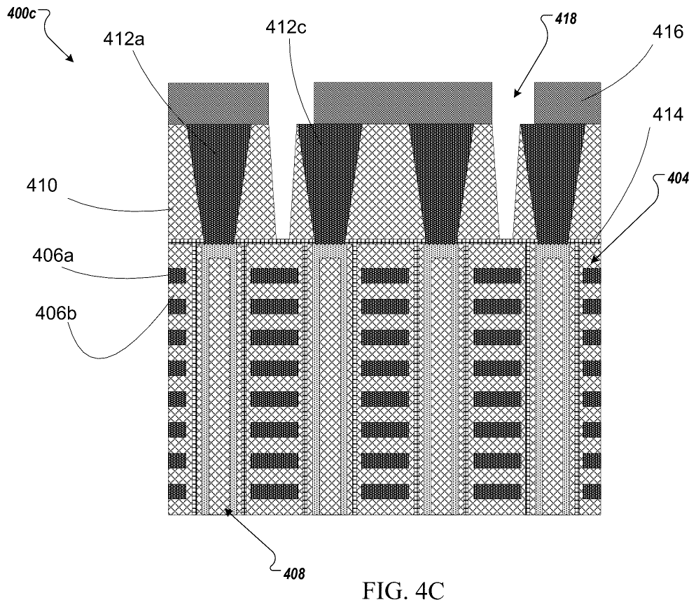

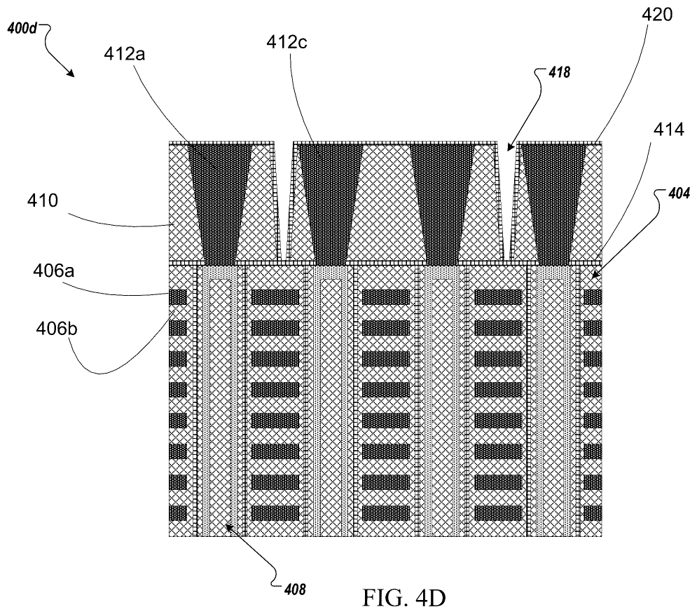

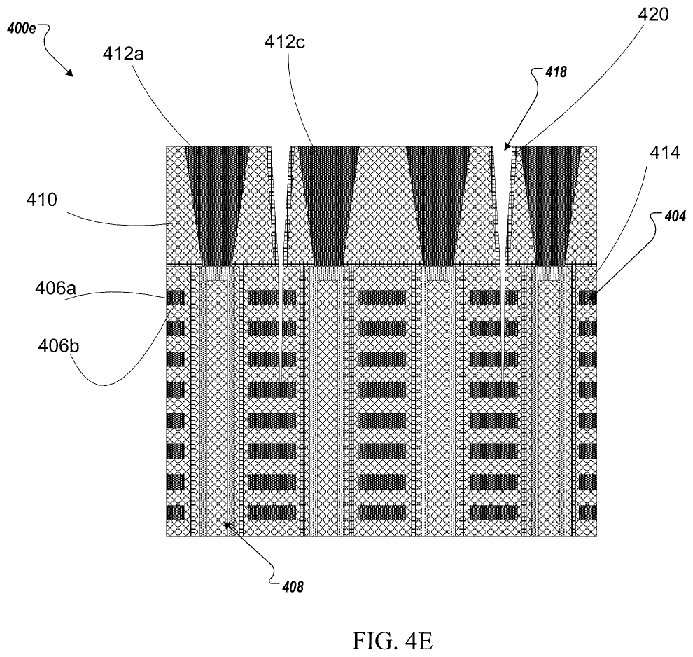

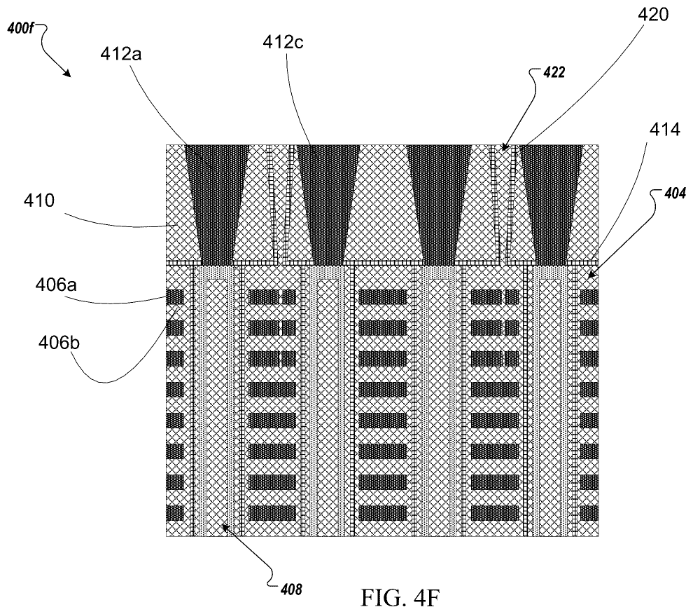

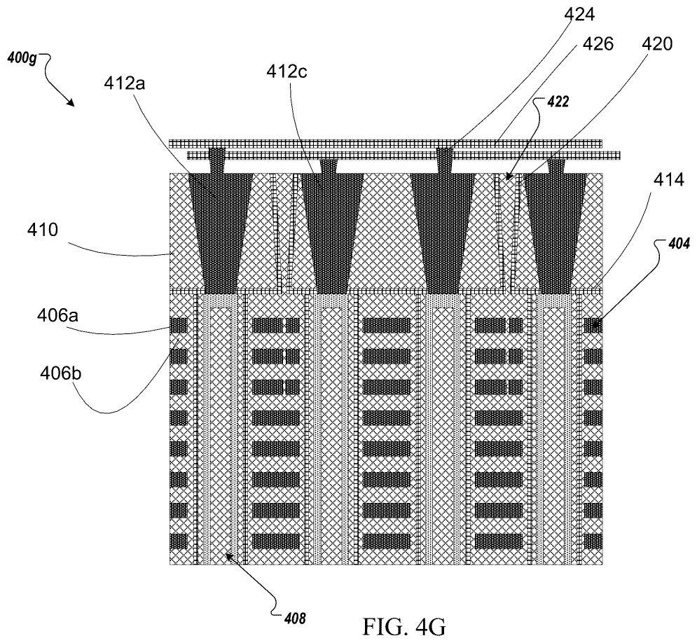

FIGS. 4A-4G illustrate an example process of fabricating a semiconductor device, such as the semiconductor device 200d as illustrated in FIG. 2D. FIGS. 4A-4G show cross-sectional views of example semiconductor structures at various stages of the fabrication process.

As shown in FIG. 4A, a semiconductor structure 400a is formed. The semiconductor structure 400a includes a stack 404 of conductive layers 406a and isolating layers 406b that alternate with each other along a vertical direction (e.g., Z direction). The semiconductor structure 400a also includes a channel structure 408 that extends through the stack 404 along the Z direction.

FIG. 4B illustrates a semiconductor structure 400b, which can be formed by depositing a dielectric material on top of the stack 404 to form a dielectric layer 410. The semiconductor structure 400b can include conductive structures 412. The conductive structures 412 are formed by etching through a portion of the dielectric layer 410 along a vertical direction (e.g., the Z direction) and filling the portion of the etched dielectric layer 410 with a conductive material. The conductive structures 412 are connected to the corresponding channel structures 408 of the stack 404 along the Z direction. In some implementations, the conductive structures 412 are in contact with the corresponding channel structures 408 of the stack 404 along the Z direction. In some implementations, the semiconductor structure 400b can also include an insulating layer 414 stacked between the dielectric layer 410 and the stack 404, which can be formed by depositing an insulating material on the stack 404 along the Z direction. In some implementations, the insulating layer 414 can be used as an etch stop layer during the fabrication process. For example, forming the conductive structure 412 includes etching a portion of the dielectric layer along the Z direction, where the etching process is stopped by the insulating layer 414, deepening the etched portion by etching through the insulation layer 414, and filling the portion of etching dielectric layer 310 with a conductive material.

FIG. 4C illustrates a semiconductor structure 400c, which can be formed by depositing a sacrificial material on top of the semiconductor structure 400b to form a sacrificial layer 416. The semiconductor structure 400c also includes one or more spaces 418. The one or more spaces 418 are formed by etching through a portion of the sacrificial layer 416 and the dielectric layer 410 along the Z direction. In some implementations, the conductive structures 412 include first conductive structures 412a and third conductive structures 412c. The one or more spaces 418 are connected to corresponding second conductive structures 412b of the semiconductor structure 400c.

FIG. 4D illustrates a semiconductor structure 400d, which can be from by removing the sacrificial layer 416 on the surface of the semiconductor structure 400c. The semiconductor structure 400d can include an outer layer 420. The outer layer 420 can be formed by depositing a dielectric material on the inner wall of the one or more spaces 418 and on top of the dielectric layer 410. In some implementations, the dielectric material of the outer layer 420 can be similar to, or same as the dielectric material of the insulating layer 414.

FIG. 4E illustrates a semiconductor structure 400e, which can be formed by deepening the one or more spaces 418 by etching through the outer layer 420, at least one conductive layer 406a of the stack 404 from an end of the one or more spaces 418 along the Z direction and removing a portion of the outer layer 420 on the surface of the dielectric layer 410. The outer layer 420 is used as a protective layer during the etching of the stack 404 to protect the channel structure 408. The end of the one or more spaces 418 is connected to the stack 404. In some implementations, the semiconductor structure 400e include the insulating layer 414, and the semiconductor structure 400e can be formed by etching through the insulating layer 414, the outer layer 420, and the at least one conductive layer 406a of the stack 404 from the end of the one or more spaces 418 along the Z direction. In some implementations, the third conductive structures 412c are connected to the outer layer 420 of the one or more spaces 418.

FIG. 4F illustrates a semiconductor structure 400f, which can be formed by depositing a dielectric material into the one or more spaces 418 to form isolation structures 422. In some implementations, the dielectric material of the isolation structures 422 is similar to, or same as the dielectric material of the dielectric layer 410 and the dielectric material of the isolating layer 406b of the stack 404.

FIG. 4G illustrates a semiconductor structure 400g, which can be formed by depositing a conductive material on top of the conductive structures 412 to form coupling-out structures 424, where the conductive structures 412 in the dielectric layer 410 are connected to interconnect structures 426 through the coupling-out structures 424.

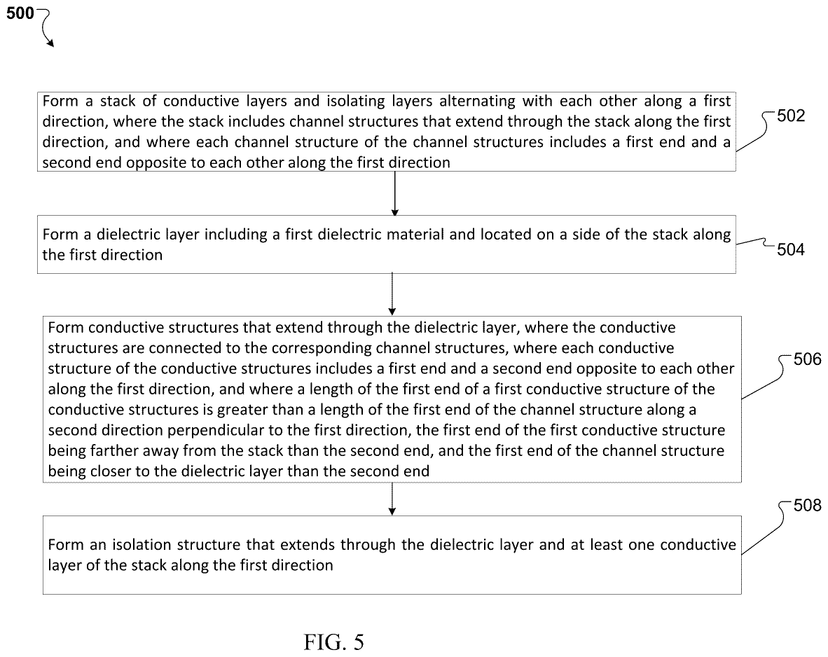

FIG. 5 illustrates a flow chart of an example process 500. The process 500 can be performed to form a semiconductor device (e.g., the semiconductor device 200a illustrated by FIG. 2A or the semiconductor device 200d illustrated by FIG. 2D). The process 500 can be described in view of FIGS. 3A-3F and FIGS. 4A-4G. The process 500 can include one or more steps of the fabrication process of forming the semiconductor structures in FIGS. 3A-3F and FIGS. 4A-4G. It is understood that the operations shown in process 500 are not exhaustive and that other operations can be performed as well before, after, or between any of the illustrated operations. Further, some of the operations may be performed simultaneously, or in a different order than shown in FIG. 5.

At operation 502, a stack (e.g., the stack 304 of FIG. 3A or the stack 404 of FIG. 4A) of conductive layers (e.g., the conductive layers 306a of FIG. 3A or the conductive layers 406a of FIG. 4A) and isolating layers (e.g., the isolating layers 306b of FIG. 3A or the isolating layers 406b of FIG. 4A) alternating with each other along a first direction (e.g., the Z direction) is formed. The stack includes channel structures (e.g., the channel structures 308 of FIG. 3A or the channel structures 408 of FIG. 4A) that extend through the stack along the first direction, and where each channel structure of the channel structures includes a first end and a second end opposite to each other along the first direction.

At operation 504, a dielectric layer (e.g., the dielectric layer 310 of FIG. 3B or the dielectric layer 410 of FIG. 4B) including a first dielectric material and located on a side of the stack along the first direction is formed.

At operation 506, conductive structures (e.g., the conductive structures 312 of FIG. 3B or the conductive structures 412 of FIG. 4B) that extend through the semiconductor layer is formed. The conductive structures are connected to the corresponding channel structures where each conductive structure of the conductive structures includes a first end and a second end opposite to each other along the first direction, and where a length of the first end (e.g., the 210a-1 of FIG. 2B or FIG. 2D) of a first conductive structure (e.g., the first conductive structure 312a of FIG. 3C or the first conductive structure 412a of FIG. 4C) of the conductive structures is greater than a length of the first end of the channel structure along a second direction (e.g., the Y direction) perpendicular to the first direction, the first end of the first conductive structure being farther away from the stack than the second end, and the first end of the channel structure being closer to the dielectric layer than the second end.

At operation 508, an isolation structure (e.g., the isolation structure 320 of FIG. 3E or the isolation structure 422 of FIG. 4F) that extends through the dielectric layer and at least one conductive layer of the stack along the first direction is formed.

In some implementations, forming the isolation structure includes etching through the dielectric layer to form a first space (e.g., the one or more spaces 318 of FIG. 3C), where the first space is in contact with a corresponding conductive structure; deepening the first space by etching through at least one conductive layer of the stack from an end of the first space along the first direction and etching a portion of the corresponding conductive structure to from a second conductive structure (e.g., the second conductive structure 312b of FIG. 3D), the end of the first space being connected to the stack; and filling a dielectric material into the first space to form the isolation structure, where the isolation structure is between two adjacent channel structures along the second direction, and where the isolation structure is spaced from the channel structures along the second direction.

In some implementations, before forming the dielectric layer, forming an insulating layer (e.g., the insulating layer 314 of FIG. 3B or the insulating layer 414 of FIG. 4B) by depositing a dielectric material on the end of the stack, where the insulating layer is stacked between the stack and the insulating layer, and where the conductive structures extend through the insulating layer and are connected to the corresponding channel structures.

In some implementations, forming the isolation structure includes etching through the dielectric layer to form a second space (e.g., the one or more spaces 318 of FIG. 3C), where the second space are in contact with a corresponding conductive structure (e.g., the second conductive structure 312b of FIG. 3D); etching through the insulating layer at an end of the second space along the first direction, the end of the second space being connected to the insulation layer; deepening the second space by etching through at least one conductive layer of the stack from the end of the second space along the first direction and etching a portion of the corresponding conductive structure to from a second conductive structure; and filling a dielectric material into the second space to form the isolation structure, where the isolation structure is between two adjacent channel structures along the second direction, and where the isolation structure is spaced from the channel structures along the second direction.

In some implementations, the second conductive structure includes a first end and a second end along the first direction, and where the length of the first end of the first conductive structure is greater than a length of a first end (e.g., the end 210b-1 of FIG. 2B) of the second conductive structure along the second direction, the first end of the second conductive structure being farther away from the stack than the second end.

In some implementations, the isolation structure further includes an outer layer (e.g., the outer layer 420 of FIG. 4D) in the dielectric layer, and where the forming the isolation structure includes etching through the dielectric layer to form a third space (e.g., the one or more spaces 418 of FIG. 4D), where the third space are in contact with a corresponding conductive structure; depositing an insulating layer on an inner wall of the third space; deepening the third space by etching through the insulating layer and at least one conductive layer of the stack from an end of the third space along the first direction, the end of the third space being connected to the stack; and filling a dielectric material into the third space to form the isolation structure, where the isolation structure is between two adjacent channel structures along the second direction, the isolation structure is spaced from the channel structures along the second direction.

In some implementations, the conductive structures further includes a third conductive structure (e.g., the third conductive structure 412c of FIG. 4B) that is partially surrounded by the isolation structure, and where the third conductive structure is in contact with the outer layer of the isolation structure in the dielectric layer along the second direction. In some implementations, the operation further includes forming coupling-out structures (e.g., the coupling-out structures 322 of FIG. 3F and the coupling-out structures 424 of FIG. 4G), where the conductive structures in the dielectric layer are connected to interconnect structures (e.g., the interconnect structures 324 of FIG. 3F and the interconnect structures 426 of FIG. 4G) through coupling-out structures.

In some implementations, the coupling-out structures are in contact with the first end of the conductive structures, and where a length of the first end of the second conductive structure is at least two times greater than a length of the coupling-out structure along the second direction.

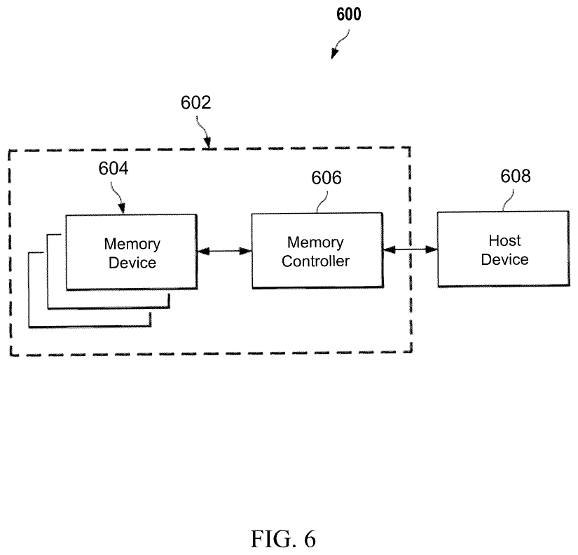

FIG. 6 illustrates a block diagram of an example system 600. The system 600 can have one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 6, the system 600 can include a host device 608 and a memory system 602 having one or more memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more memory devices 604.

A memory device 604 can be any memory device disclosed in the present disclosure, such as a memory device (e.g., a NAND Flash memory) as shown in FIG. 1 and FIGS. 2A-2F. Memory controller 606 (a.k.a., a controller circuit) is coupled to memory device 604 and host device 608. Consistent with implementations of the present disclosure, memory device 604 can include a plurality of conductive interconnections through a cover layer that are in contact with conductive pads in a conductive pad layer, and memory controller 606 can be coupled to memory device 604 through at least one of the plurality of conductive interconnections. Memory controller 606 is configured to control memory device 604. For example, memory controller 606 may be configured to operate a plurality of channel structures via word lines. Memory controller 606 can manage data stored in memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of memory device 604, such as read, erase, and program (or write) operations. Memory controller 606 can also be configured to manage various functions with respect to the data stored or to be stored in memory device 604 including, but not limited to bad-block management, garbage collection, logical-to-physical address conversion, wear leveling, etc. In some implementations, memory controller 606 is further configured to process error correction codes (ECCs) with respect to the data read from or written to memory device 604. Any other suitable functions may be performed by memory controller 606 as well, for example, formatting memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a stack of conductive layers and isolating layers alternating with each other along a first direction;
a channel structure that extends through the stack, wherein the channel structure comprises a first end and a second end opposite to each other along the first direction;
a dielectric layer comprising a first dielectric material and located on a side of the stack along the first direction;
a first conductive structure that extends through the dielectric layer, wherein the first conductive structure is connected to the corresponding channel structure, wherein the first conductive structure comprises a first end and a second end opposite to each other along the first direction, and
wherein a length of the first end of a first conductive structure is greater than a length of the first end of the channel structure along a second direction perpendicular to the first direction, the first end of the first conductive structure being farther away from the stack than the second end, and the first end of the channel structure being closer to the dielectric layer than the second end; and
an isolation structure that extends through the dielectric layer and at least one conductive layer of the stack along the first direction.

2. The semiconductor device of claim 1, wherein the isolation structure is between two adjacent channel structures along the second direction, and wherein the isolation structure is spaced from the channel structures along the second direction.

3. The semiconductor device of claim 2, wherein the semiconductor device further comprises an insulating layer located between the stack and the dielectric layer, and wherein the isolation structure extends through the insulating layer along the first direction.

4. The semiconductor device of claim 1, wherein, along the second direction, the length of the first end of the first conductive structure is greater than a length of the second end of the first conductive structure, and wherein the second end of the first conductive structure is in contact with the first end of the channel structure along the first direction.

5. The semiconductor device of claim 4, wherein the channel structure further comprises a channel plug in contact with the second end of the first conductive structure along the first direction, and wherein the length of the first end of the channel structure is greater than the length of the second end of the first conductive structure along the second direction.

6. The semiconductor device of claim 1, wherein the semiconductor device comprises a second conductive structure having a first end and a second end opposite to each other along the first direction, wherein the second conductive structure is connected to the corresponding channel structure, and wherein the length of the first end of the first conductive structure is greater than a length of a first end of the second conductive structure along the second direction, the first end of the second conductive structure being farther away from the stack than the second end of the second conductive structure.

7. The semiconductor device of claim 1, wherein the isolation structure comprises an outer layer in the dielectric layer, wherein the outer layer comprises a second dielectric material, and wherein the first dielectric material of the dielectric layer is different from the second dielectric material of the outer layer of the isolation structure.

8. The semiconductor device of claim 7, wherein the semiconductor device comprises a third conductive structure that is partially surrounded by the isolation structure, the third conductive structure is connected to the corresponding channel structure, and
wherein the third conductive structure is in contact with the outer layer of the isolation structure in the dielectric layer along the second direction.

9. The semiconductor device of claim 6, wherein the first conductive structure and the second conductive structure in the dielectric layer are connected to interconnect structures through coupling-out structures.

10. The semiconductor device of claim 9, wherein a length of the first end of the second conductive structure is at least two times greater than a length of the coupling-out structure along the second direction.

11. A method of forming a semiconductor device, wherein the method comprises:
forming a stack of conductive layers and isolating layers alternating with each other along a first direction, wherein the stack comprises channel structure that extends through the stack along the first direction, and wherein the channel structure comprises a first end and a second end opposite to each other along the first direction;
forming a dielectric layer comprising a first dielectric material and located on a side of the stack along the first direction;
forming a first conductive structure that extends through the dielectric layer, wherein the first conductive structure is connected to the corresponding channel structure, wherein the first conductive structure comprises a first end and a second end opposite to each other along the first direction, and
wherein a length of the first end of a first conductive structure is greater than a length of the first end of the channel structure along a second direction perpendicular to the first direction, the first end of the first conductive structure being farther away from the stack than the second end, and the first end of the channel structure being closer to the dielectric layer than the second end; and
forming an isolation structure that extends through the dielectric layer and at least one conductive layer of the stack along the first direction.

12. The method of claim 11, wherein forming the isolation structure comprises:
etching through the dielectric layer to form a first space, wherein the first space is in contact with a corresponding conductive structure;
deepening the first space by etching through at least one conductive layer of the stack from an end of the first space along the first direction and etching a portion of the corresponding conductive structure to from a second conductive structure, the end of the first space being connected to the stack; and
filling a dielectric material into the first space to form the isolation structure, wherein the isolation structure is between two adjacent channel structures along the second direction, and wherein the isolation structure is spaced from the channel structures along the second direction.

13. The method of claim 11, further comprising:
before forming the dielectric layer, forming an insulating layer by depositing a dielectric material on the end of the stack, wherein the insulating layer is stacked between the stack and the insulating layer, and
wherein the conductive structure extends through the insulating layer and are connected to the corresponding channel structures.

14. The method of claim 13, wherein forming the isolation structure further comprises:
etching through the dielectric layer to form a second space, wherein the second space are in contact with a corresponding conductive structure;
etching through the insulating layer at an end of the second space along the first direction, the end of the second space being connected to the insulation layer;
deepening the second space by etching through at least one conductive layer of the stack from the end of the second space along the first direction and etching a portion of the corresponding conductive structure to from a second conductive structure; and
filling a dielectric material into the second space to form the isolation structure, wherein the isolation structure is between two adjacent channel structures along the second direction, and wherein the isolation structure is spaced from the channel structures along the second direction.

15. The method of claim 12, wherein the second conductive structure comprises a first end and a second end opposite to each other along the first direction, and wherein the length of the first end of the first conductive structure is greater than a length of a first end of the second conductive structure along the second direction, the first end of the second conductive structure being farther away from the stack than the second end.

16. The method of claim 11, wherein the isolation structure further comprises an outer layer in the dielectric layer, and wherein the forming the isolation structure comprises:
etching through the dielectric layer to form a third space, wherein the third space are in contact with a corresponding conductive structure;
depositing an insulating layer on an inner wall of the third space;
deepening the third space by etching through the insulating layer and at least one conductive layer of the stack from an end of the third space along the first direction, the end of the third space being connected to the stack; and
filling a dielectric material into the third space to form the isolation structure, wherein the isolation structure is between two adjacent channel structures along the second direction, the isolation structure is spaced from the channel structures along the second direction.

17. The method of claim 16, wherein the semiconductor device further comprises a third conductive structure that is partially surrounded by the isolation structure, and
wherein the third conductive structure is in contact with the outer layer of the isolation structure in the dielectric layer along the second direction.

18. The method of claim 14, further comprising:
forming coupling-out structures, wherein the first conductive structure and the second conductive structure in the dielectric layer are connected to interconnect structures through the coupling-out structures.

19. The method of claim 18, wherein a length of the first end of the second conductive structure is at least two times greater than a length of the coupling-out structure along the second direction.

20. A memory system, comprising:
a memory device; and
a memory controller coupled to the memory device and configured to control the memory device,
wherein the memory device comprises:
a stack of conductive layers and isolating layers alternating with each other along a first direction;
a channel structure that extends through the stack, wherein the channel structure comprises a first end and a second end opposite to each other along the first direction;
a dielectric layer comprising a first dielectric material and located on a side of the stack along the first direction;
a first conductive structure that extends through the dielectric layer, wherein the first conductive structure is connected to the corresponding channel structure, wherein the first conductive structure comprises a first end and a second end opposite to each other along the first direction, and
wherein a length of the first end of a first conductive structure is greater than a length of the first end of the channel structure along a second direction perpendicular to the first direction, the first end of the first conductive structure being farther away from the stack than the second end, and the first end of the channel structure being closer to the dielectric layer than the second end; and
an isolation structure that extends through the dielectric layer and at least one conductive layer of the stack along the first direction.
